(19) United States
(12) Patent Application Publication
(10) Pub. No.: US 2009/0178615 A1
(43) Pub. Date: Jul. 16, 2009

(54) SHOWERHEAD AND CHEMICAL VAPOR DEPOSITION APPARATUS HAVING THE SAME

(75) Inventors: Changsung Sean KIM, Yongin (KR); Chang Hwan Choi, Seongnam (KR); Jong Pa Hong, Yongin (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/196,453

(22) Filed: Aug. 22, 2008

(30) Foreign Application Priority Data
Jan. 15, 2008 (KR) 10-2008-0004418

(51) Int. Cl. C23C 16/00

(52) U.S. Cl. 118/715

(57) ABSTRACT

There is provided a showerhead including: a first head having at least one gas conduit provided therein to allow a first reaction gas to be supplied into a reaction chamber; a second head having a hole of a predetermined size formed to have the gas conduit extending therethrough; and a gas flow path formed between the gas conduit extending through the hole and the hole to allow a second reaction gas to be supplied into the reaction chamber.

### CROSS-REFERENCE TO RELATED APPLICATIONS

This application claims the priority of Korean Patent Application No. 2008-0004418 filed on Jan. 15, 2008, in the Korean Intellectual Property Office, the disclosure of which is incorporated herein by reference.

### BACKGROUND OF THE INVENTION

1. Field of the Invention

The present invention relates to a showerhead and a chemical vapor deposition apparatus having the same, and more particularly, to a showerhead improved in a jet structure of a reaction gas and a chemical vapor deposition apparatus having the same.

2. Description of the Related Art

In general, chemical vapor deposition (CVD) is a process in which a reaction gas supplied into a reaction chamber reacts chemically on a top surface of a heated wafer so as to grow a thin film. This thin film growth method ensures superior crystal quality over a liquid phase growth but entails a relatively slow crystal growth rate. In a widely used method for overcoming this drawback, thin films are grown simultaneously on several substrates in one growth cycle.

A general chemical vapor deposition apparatus includes a reaction chamber having an inner space of a predetermined size, a susceptor installed in the inner space to have a wafer, an object of deposition, mounted thereon, a heating unit disposed adjacent to the susceptor to supply predetermined heat and a showerhead jetting a reaction gas to the wafer mounted on the susceptor.

### SUMMARY OF THE INVENTION

An aspect of the present invention provides a showerhead capable of simplifying a process of assembling heads together in a less time to enhance work productivity and save manufacturing costs.

An aspect of the present invention also provides a showerhead which ensures minimum vortex to occur during mixing of different reaction gases to inhibit parasitic deposition on a bottom end of a head.

An aspect of the present invention also provides a chemical vapor deposition apparatus capable of shortening a length of a section where different reaction gases are mixed together to reduce a height of a reaction chamber, thereby leading to reduction in an overall volume thereof.

According to an aspect of the present invention, there is provided a showerhead including: a first head having at least one gas conduit provided therein to allow a first reaction gas to be supplied into a reaction chamber; a second head having a hole of a predetermined size formed to have the gas conduit extending therethrough; and a gas flow path formed between the gas conduit extending through the hole and the hole to allow a second reaction gas to be supplied into the reaction chamber.

The gas flow path may be defined by an interval of a predetermined size between an inner surface of the hole and an outer surface of the gas conduit.

The gas conduit may be substantially center-aligned with the hole.

The gas conduit may have a bottom end substantially flush with a bottom end of the hole.

The gas conduit may have a thickness adjusted to change a length of a mixing section where the first reaction gas and the second reaction gas are mixed together.

The gas conduit may be formed of a hollow member having at least one gas jet opening to jet the first reaction gas therethrough.

The showerhead may further include: a third head disposed between the first and second heads, the third head having a supply conduit with a predetermined inner space such that the gas conduit is inserted thereinto; and a supply flow path formed between the supply conduit and the gas conduit to supply a third reaction gas into the reaction chamber.

The gas flow path may be formed between an outer surface of the gas conduit and the hole, and the supply flow path may be formed between an inner surface of the supply conduit and an inner surface of the gas conduit.

The gas conduit, the hole and the supply conduit may be substantially center-aligned with one another.

The gas conduit and the supply conduit may have a thickness adjusted, respectively to change a length of a mixing section where the first, second and third reaction gases are mixed together.

According to another aspect of the present invention, there is provided a chemical vapor deposition apparatus including: a reaction chamber; a first head having at least one gas conduit provided therein to allow a first reaction gas to be supplied into a reaction chamber; a second head having a hole of a predetermined size formed to have the gas conduit extending therethrough; and a gas flow path formed between the gas conduit extending through the hole and the hole to allow a second reaction gas to be supplied into the reaction chamber.

The gas flow path may be defined by an interval of a predetermined size between an inner surface of the hole and an outer surface of the gas conduit.

The gas conduit may be center-aligned with the hole.

The gas conduit may have a thickness adjusted to change a length of a mixing section where the first reaction gas and the second reaction gas are mixed together.

The gas conduit may be formed of a hollow member having at least one gas jet opening to jet the first reaction gas therethrough.

The chemical vapor deposition apparatus may further include: a third head disposed between the first and second heads, the third head having a supply conduit with a predetermined inner space such that the gas conduit is inserted thereinto; and a supply flow path formed between the supply conduit and the gas conduit to supply a third reaction gas into the reaction chamber.

The gas flow path may be formed between an outer surface of the gas conduit and the hole, and the supply flow path may be formed between an inner surface of the supply conduit and an inner surface of the gas conduit.

The gas conduit, the hole and the supply conduit may be substantially center-aligned with one another.

The gas conduit and the supply conduit may have a thickness adjusted, respectively to change a length of a mixing section where the first, second and third reaction gases are mixed together.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a chemical vapor deposition apparatus having a showerhead according to an exemplary embodiment of the invention;

FIG. 2 is an exploded perspective view illustrating a showerhead according to an exemplary embodiment of the invention;

FIG. 3 is a cross-sectional view of a B portion shown in FIG. 2;

FIG. 4 is a cross-sectional view illustrating a showerhead according to another exemplary embodiment of the invention; and

FIGS. 5A to 5C are perspective views illustrating a gas flow path employed in a showerhead according to an exemplary embodiment of the invention.

### DETAILED DESCRIPTION OF THE PREFERRED EMBODIMENT

Exemplary embodiments of the present invention will now be described in detail with reference to the accompanying drawings.

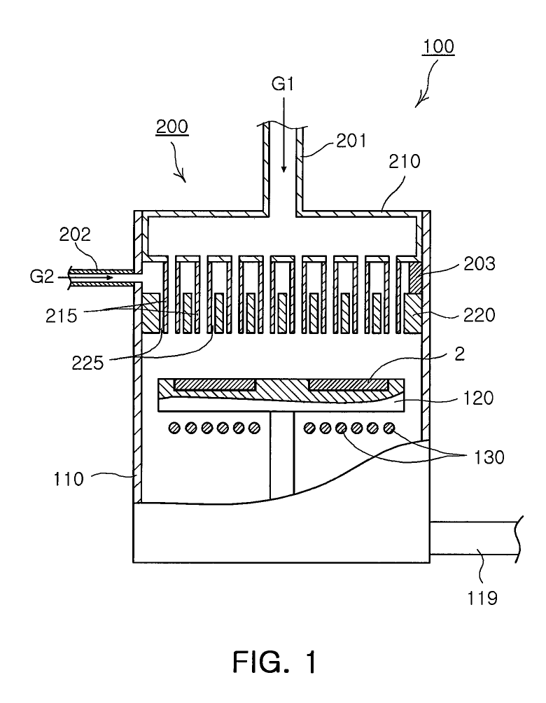

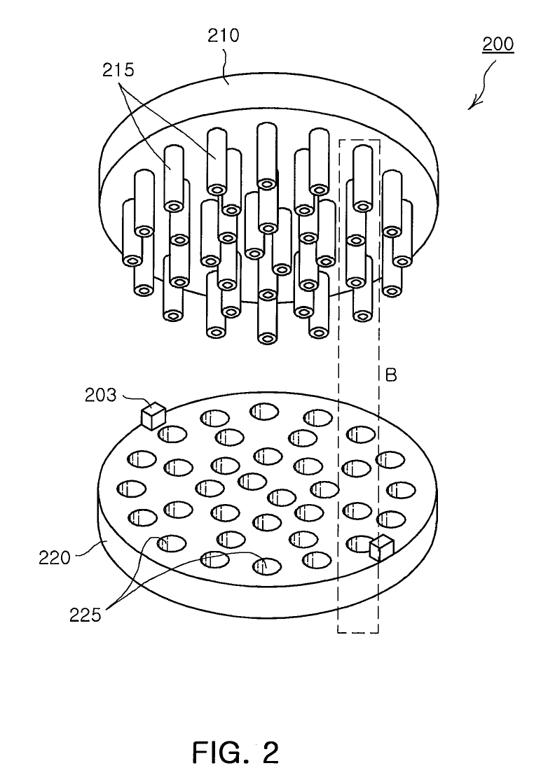

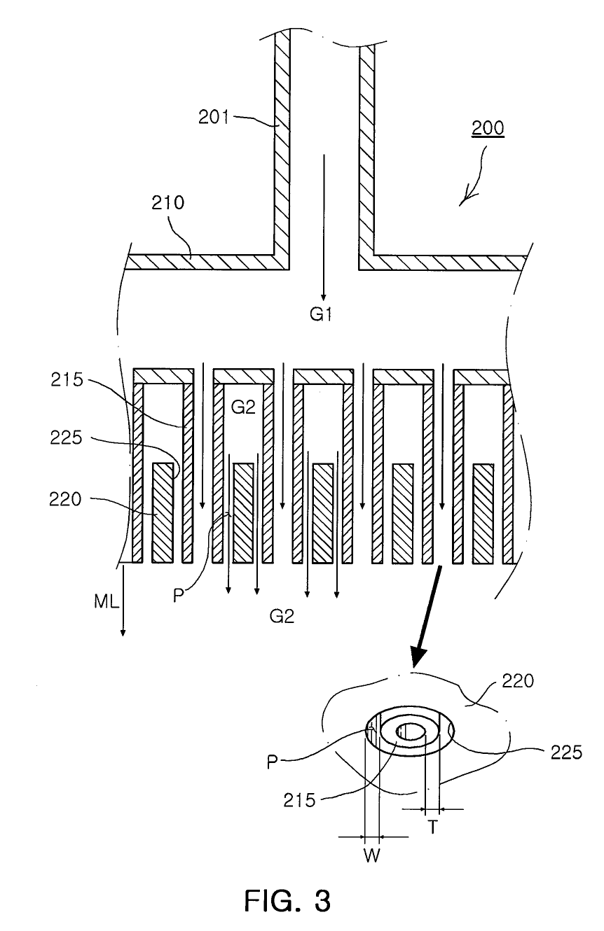

FIG. 1 is a cross-sectional view illustrating a chemical vapor deposition apparatus having a showerhead according to an exemplary embodiment of the invention. FIG. 2 is an exploded perspective view illustrating a showerhead according to an exemplary embodiment of the invention. FIG. 3 is a cross-sectional view of a B portion shown in FIG. 2.

As shown in FIGS. 1 to 3, the chemical vapor deposition apparatus 100 of the present embodiment includes a reaction chamber 110, a susceptor 120, a heating unit 130 and a showerhead 200.

The reaction chamber 110 has an inner space of a predetermined size where a reaction gas fed thereinto and a wafer 2 to be deposited undergo chemical deposition reaction therebetween. The reaction chamber 110 may have a heat insulating material provided on an inner surface thereof to withstand a high temperature atmosphere.

The reaction chamber 110 is provided with an outlet 119 for exhausting a waste gas produced after chemical deposition reaction with the wafer 2.

The susceptor 120 has at least one pocket recessed in a top surface thereof to support the wafer disposed inside the reaction chamber 110.

The susceptor 120 is formed in a disc shape and made of graphite. The susceptor 120 has a rotational axis provided on a center of a bottom surface to connect to an unillustrated driving motor. Accordingly, a rotational driving force generated by the driving motor allows the susceptor 120 having the wafer 2 mounted thereon to rotate at a uniform rate of about 5 to 50 rpm in one direction.

The heating unit 130 is disposed near the bottom surface of the susceptor 120 where the wafer 2 is mounted to supply heat to the susceptor 120 and heat the wafer 2.

This heating unit 130 may be formed of one of an electric heater, a high frequency inductor, an infrared radiator and a laser.

Also, a temperature sensor (not shown) may be disposed in the reaction chamber 110 to be within proximity of an outer surface of the susceptor 120 or the heating unit 130. This temperature sensor measures an internal ambient temperature of the reaction chamber 110 irregularly and adjusts a heating temperature based on measured results.

Meanwhile, the showerhead 200 is installed in an upper portion of the reaction chamber 110 to jet at least one kind of reaction gas onto the wafer 2 mounted on the susceptor 120 so as to be in uniform contact with the wafer 2. This showerhead 200 includes a first head 210 and a second head 220.

The first head 210 is connected to a first supply line 210 from which a first reaction gas G1 is supplied so that the first reaction gas G1 is filled in an inner space of the first head 210 through the first supply line 201.

At least one gas conduit 215 with a predetermined length is provided on a bottom surface of the first head 210 to allow the first reaction gas G1 to be jetted into the reaction chamber 110 therethrough.

Referring to FIGS. 1 to 5, the first head 210 is illustrated to include the plurality of gas conduits 215.

The second head 220 has holes 225 of a predetermined size formed therein to have the gas conduit 215 inserted thereinto.

In the present embodiments shown in FIGS. 1 to 3, the first head 210 and the second head 220 are disposed in the upper portion of the reaction chamber 110. A spacer 203 is disposed between the first and second heads 210 and 230 such that the first head 210 and the second head 220 maintain a vertical interval therebetween to define an inner space of a predetermined size.

The inner space defined by the spacer 203 is in communication with a second supply line 202. A second reaction gas G2 is fed into the reaction chamber 110 through the second supply line 202.

Also, as shown in FIGS. 1 to 3, the first head 210 and the second head 220 are arranged such that each of the gas conduits 215 extends through each of the holes 225. An outer surface of the gas conduit 215 and the hole 225 have a predetermined interval therebetween.

That is, the predetermined interval between the gas conduit 215 and the hole 225 defines a gas flow path P allowing the second reaction gas G2 fed through the second supply line 202 to be supplied into the reaction chamber 110.

Therefore, the first reaction gas G1 supplied through the first supply line 201 of the first head 210 is supplied into the reaction chamber through the gas conduit 215. The second reaction gas G2 supplied through the second supply line 202 is supplied into the reaction chamber through the gas flow path P. Then the first and second gases G1 and G2 are mixed together in a portion below the gas conduit 215 and the hole 225.

Here, an area between the portion below the gas conduit 215 or the hole 225 and the susceptor 120 is a mixing section where the first reaction gas G1 supplied through the gas conduit 215 and the second reaction gas G2 supplied through the gas flow path P are mixed together.

As a result, the first reaction gas G1 supplied into the first head 210 is jetted into the reaction chamber 110 through the gas conduit 215. The second reaction gas G2 supplied through a portion between the first head 210 and the second head 220 is supplied into the reaction chamber 110 through the gas flow path P formed between the gas conduit 215 and the hole 225. The first reaction gas G1 and the second reaction gas G2 supplied into the reaction chamber 110 are mixed together at the mixing section.

Moreover, when the first head 210 and the second head 220 are assembled together, the gas conduit 215 of the first head 210 is inserted into the hole 225 of the second head 220 smoothly. This does not require high precision as in the conventional art and precludes a need for welding, thereby alleviating laborer's burden and simplifying an assembly process to shorten an assembly time.

Here, the gas conduits 215 of the first head 210 may be identical in number to the holes 225 of the second head 220.

Furthermore, the gas conduit 215 and the hole 225 are center-aligned with each other to allow the second reaction gas G2 to be jetted through the interval W more uniformly.

Also, a bottom end of the gas conduit 215 and a bottom end of the hole 225 are formed substantially flush with a bottom end of the second head 220. This allows the second reaction gas G2 jetted through the gas flow path P and the first reaction gas G1 jetted through the gas conduit 215 to be mixed together more smoothly.

Meanwhile, as shown in FIG. 3, the mixing section of the first reaction gas G1 jetted from the gas conduit 215 and the second reaction gas G2 jetted from the gas flow path P has a length ML increased or decreased in a downward direction by changing a thickness T of the gas conduit 215 disposed in the hole 225.

That is, when the gas conduit 215 has a thickness T increased, while maintaining the interval W of the gas flow path P as constant, the first reaction gas G1 is jetted through the gas conduit in a narrow area and at a smaller angle to accelerate a gas jet rate. This further lengthens the mixing section of the first reaction gas G1 and the second reaction gas G2 jetted through the gas flow path P.

That is, the mixing section where the first reaction gas G1 and the second reaction gas G2 are mixed together sufficiently is increased in length.

On the other hand, when the gas conduit 215 has a thickness T decreased, while maintaining the interval W of the gas flow path P as constant, the first reaction gas G1 is jetted through the gas conduit 215 in a larger area and at a bigger angle to slow down a gas jet ratio. This further shortens the mixing section of the first reaction gas G1 and the second reaction gas G2 jetted through the gas flow path P.

That is, the mixing section where the first reaction gas G1 and the second reaction gas G2 are mixed together sufficiently is reduced in length.

Therefore, by decreasing the thickness of the gas conduit 215, a vertical interval between the second head 220 and the susceptor 120 is decreased to reduce an entire height of the reaction chamber 110 and accordingly ensure a smaller apparatus. Also, this requires a less amount of reaction gas to be consumed and assures a uniform gas flow to thereby produce a growth layer of uniform quality.

Moreover, the first reaction gas G1 and the second reaction gas G2 are mixed together after a predetermined distance, thus preventing parasitic deposition from occurring on the bottom end of the gas conduit 215 or the bottom end of the second head 220.

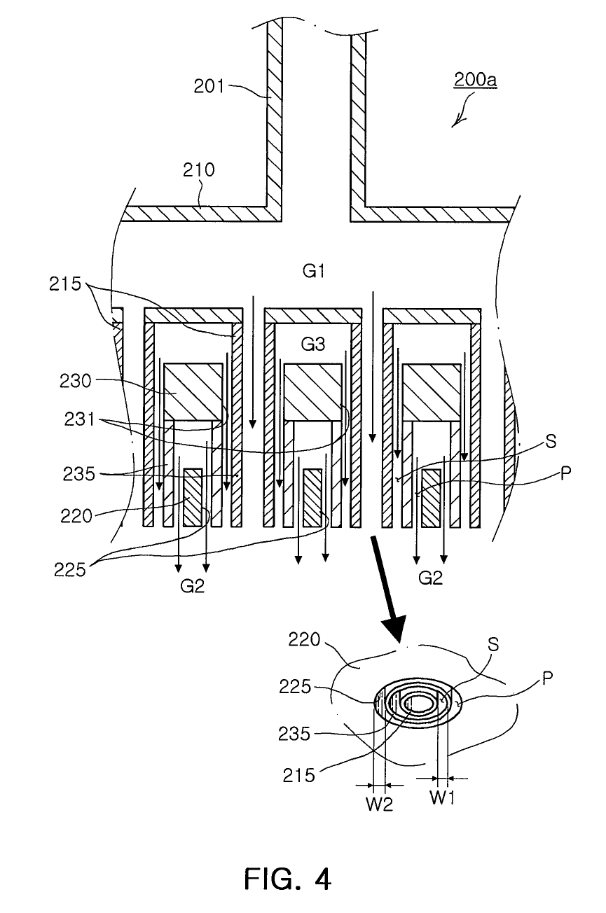

Furthermore, as shown in FIGS. 1 to 3, the bottom end of the gas conduit 215 and the bottom end of the hole 225 are substantially flush with each other. This further enhances a mixing efficiency of the first reaction gas G1 supplied through the gas conduit 215 and the second reaction gas G2 supplied through the gas flow path P of the hole 225. This is identically applied to another exemplary embodiment of the invention which will be described later with reference to FIG. 4.

FIG. 4 is a cross-sectional view illustrating a showerhead according to another exemplary embodiment of the invention. As shown in FIG. 4, the showerhead 200a of the present embodiment includes a third head 230 disposed between a first head 210 and a second head 220 to supply a third reaction gas G3.

The third head 230 has supply conduits 235 provided in portions corresponding to gas conduits 215 installed in the first head 210. Each of the supply conduit 235 is fixedly inserted into a corresponding one of through holes 231 perforated in the third head 230 or fixedly welded to a bottom surface of the third head 230 to be in communication with the through holes 231.

The gas conduit 215 of the first head 210 is inserted into the supply conduit 235 of the third head 230. Here, an interval W1 of a predetermined size is formed between an outer surface of the gas conduit 215 inserted into the supply conduit 235 and an inner surface of the supply conduit 235 to allow a third reaction gas fed between the first head 210 and the third head 230 to be supplied into the reaction chamber 110. That is, the interval W1 defines a supply flow path S. Also, each the supply conduit 235 of the third head 230 is inserted into each of holes 225 of the second head 220. Here, an interval W2 of a predetermined size is formed between an outer surface of the supply conduit 235 inserted into the hole 225 and an inner surface of the hole 225 to allow a second reaction gas G2 fed between the third head 230 and the second head 220 to be jetted therethrough. That is, the interval W2 defines a gas flow path P.

Here, the gas conduits 215 installed in the first head 210 may be substantially identical in number to the holes 225 formed in the second head 220 and the supply conduits 235 of the third head 230, respectively.

Also, the gas conduit 215, the hole 225 and the supply conduit 235 are substantially center-aligned with one another. This allows the second reaction gas G2 and the third reaction gas G3 to be jetted more uniformly through the gas flow path P and the supply flow path S, respectively.

Moreover, a bottom end of the gas conduit 215, a bottom end of the hole 225 and a bottom end of the supply conduit 235 are formed substantially flush with a bottom end of the second head 220. This allows the second and third reaction gases jetted through the gas flow path P and the supply flow path S, respectively to be mixed with the first reaction gas G1 jetted through the gas conduit 215 more smoothly.

In addition, a mixing section where the first reaction gas G1 jetted from the gas conduit 215, the second reaction gas G2 jetted through the gas flow path P and the third reaction gas G3 jetted through the supply flow path S may be increased or decreased in a downward direction by changing a thickness of the supply conduit 235 disposed in the hole 225 and a thickness of the gas conduit 215 inserted into the supply conduit 235.

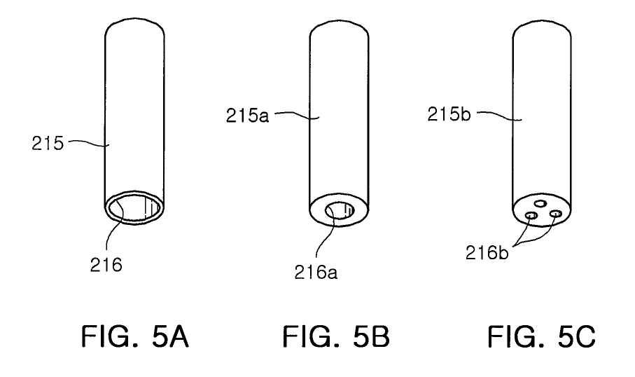

As shown in FIG. 5A, the gas conduit 215 provided in the first head 210 may be formed of a hollow cylindrical member of a predetermined length. The hollow cylindrical member may include at least one gas jet opening 216, 216a, and 216b. FIG. 5C illustrates the gas conduit 215b having the plurality of gas jet openings 216b.

The cylindrical members shown in FIGS. 5A to 5C are not necessarily limited to the gas conduit 215. These cylindrical members are substantially identically applied to the supply conduit 235. Therefore, the supply conduit 235 will not be described in detail.

As set forth above, according to exemplary embodiments of the invention, a chemical deposition apparatus is assembled such that an interval is formed between a gas flow path of a first head and a hole of a second head. This simplifies a process of assembling heads and reduces an assembling time to improve work productivity and save manufacturing costs.

Moreover, a section where two different reaction gases are mixed together is shortened in length to reduce a vertical interval between a second head and a susceptor. This accordingly reduces an overall height of a reaction chamber to ensure the apparatus to be designed with a smaller size. Also, this reduces a consumption amount of the reaction gases and allows for uniform gas flow to thereby produce a growth layer of uniform quality.

In addition, the different reaction gases are mixed together after a predetermined distance to minimize vortex occurring on a bottom surface of a head. This consequently inhibits parasitic deposition from occurring on the bottom surface of the head.

While the present invention has been shown and described in connection with the exemplary embodiments, it will be apparent to those skilled in the art that modifications and variations can be made without departing from the spirit and scope of the invention as defined by the appended claims.

What is claimed is:

1. A showerhead comprising:
a first head having at least one gas conduit provided therein to allow a first reaction gas to be supplied into a reaction chamber;
a second head having a hole of a predetermined size formed to have the gas conduit extending therethrough; and
a gas flow path formed between the gas conduit extending through the hole and the hole to allow a second reaction gas to be supplied into the reaction chamber.

2. The showerhead of claim 1, wherein the gas flow path is defined by an interval of a predetermined size between an inner surface of the hole and an outer surface of the gas conduit.

3. The showerhead of claim 1, wherein the gas conduit is substantially center-aligned with the hole.

4. The showerhead of claim 1, wherein the gas conduit has a bottom end substantially flush with a bottom end of the hole.

5. The showerhead of claim 1, wherein the gas conduit has a thickness adjusted to change a length of a mixing section where the first reaction gas and the second reaction gas are mixed together.

6. The showerhead of claim 1, wherein the gas conduit comprises a hollow member having at least one gas jet opening to jet the first reaction gas therethrough.

7. The showerhead of claim 1, further comprising:
a third head disposed between the first and second heads, the third head having a supply conduit with a predetermined inner space such that the gas conduit is inserted thereinto; and
a supply flow path formed between the supply conduit and the gas conduit to supply a third reaction gas into the reaction chamber.

8. The showerhead of claim 7, wherein the gas flow path is formed between an outer surface of the gas conduit and the hole, and the supply flow path is formed between an inner surface of the supply conduit and an inner surface of the gas conduit.

9. The showerhead of claim 7, wherein the gas conduit, the hole and the supply conduit are substantially center-aligned with one another.

10. The showerhead of claim 7, wherein the gas conduit and the supply conduit have a thickness adjusted, respectively to change a length of a mixing section where the first, second and third reaction gases are mixed together.

11. A chemical vapor deposition apparatus comprising:
a reaction chamber;
a first head having at least one gas conduit provided therein to allow a first reaction gas to be supplied into a reaction chamber;
a second head having a hole of a predetermined size formed to have the gas conduit extending therethrough; and
a gas flow path formed between the gas conduit extending through the hole and the hole to allow a second reaction gas to be supplied into the reaction chamber.

12. The chemical vapor deposition apparatus of claim 11, wherein the gas flow path is defined by an interval of a predetermined size between an inner surface of the hole and an outer surface of the gas conduit.

13. The chemical vapor deposition apparatus of claim 11, wherein the gas conduit is center-aligned with the hole.

14. The chemical vapor deposition apparatus of claim 11, wherein the gas conduit has a thickness adjusted to change a length of a mixing section where the first reaction gas and the second reaction gas are mixed together.

15. The chemical vapor deposition apparatus of claim 11, wherein the gas conduit comprises a hollow member having at least one gas jet opening to jet the first reaction gas therethrough.

16. The chemical vapor deposition apparatus of claim 11, further comprising:
a third head disposed between the first and second heads, the third head having a supply conduit with a predetermined inner space such that the gas conduit is inserted thereinto; and
a supply flow path formed between the supply conduit and the gas conduit to supply a third reaction gas into the reaction chamber.

17. The chemical vapor deposition apparatus of claim 16, wherein the gas flow path is formed between an outer surface of the gas conduit and the hole, and the supply flow path is formed between an inner surface of the supply conduit and an inner surface of the gas conduit.

18. The chemical vapor deposition apparatus of claim 16, wherein the gas conduit, the hole and the supply conduit are substantially center-aligned with one another.

19. The chemical vapor deposition apparatus of claim 16, wherein the gas conduit and the supply conduit have a thickness adjusted, respectively to change a length of a mixing section where the first, second and third reaction gases are mixed together.

20. The chemical vapor deposition apparatus of claim 16, wherein the gas conduit has a bottom end substantially flush with a bottom end of the hole.
